(19) United States
(12) Patent Application Publication
(10) Pub. No.: US 2015/0333182 A1
(43) Pub. Date: Nov. 19, 2015

(54) METHOD OF FABRICATING ARRAY SUBSTRATE, ARRAY SUBSTRATE, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Jian GUO, Beijing (CN)

(21) Appl. No.: 14/516,882

(22) Filed: Oct. 17, 2014

(30) Foreign Application Priority Data
May 16, 2014 (CN) 201410209243.6

(51) Int. Cl. H01L 29/786; H01L 29/66; H01L 21/467; H01L 27/12; H01L 21/4757; H01L 21/475; H01L 29/24; H01L 21/02

(52) U.S. Cl. CPC H01L 29/7869; H01L 29/24; H01L 29/66969; H01L 21/02565; H01L 27/124; H01L 27/1225; H01L 27/1259; H01L 21/47573; H01L 21/475; H01L 21/467

(57) ABSTRACT

The embodiments of the present invention provide a method of fabricating an array substrate, including steps of funning a thin film transistor, a pixel electrode and a common electrode line, wherein the step of forming the thin film transistor includes steps of forming patterns of a gate, a gate insulation layer, a semiconductor layer, an etch stop layer, a source and a drain, and the gate and the common electrode line are formed in the same layer. In the method, a gate insulation film and a semiconductor film are sequentially formed, and a pattern including the semiconductor layer is formed by one patterning process; and then an etch stop film is formed, and as pattern including the gate insulation layer and the etch stop layer is formed by one patterning process.

### CROSS-REFERENCE TO RELATED APPLICATION

This application claims priority under 35 U.S.C. §119 to Chinese Patent Application No. 201410209243.6, filed on May 16, 2014, in the Chinese Intellectual Property Office, the disclosure of which is incorporated by reference herein in its entirety.

### FIELD OF THE INVENTION

The present invention relates to the field of display technology, and more particularly, to a method of fabricating an array substrate, an array substrate, and a display device.

### BACKGROUND OF THE INVENTION

With the development of science and technology, a flat-panel display device replaces a heavy CRT display device to be widely used in people's daily lives. At present, the typical flat-panel display devices include a liquid crystal display (LCD) device and an organic light-emitting diode (OLED) device.

The LCD device and the OLED device both include an array substrate, the array substrate includes a plurality of pixel drive circuits which are arranged in a matrix and consist of thin film transistors (TFTs), and each pixel drive circuit corresponds to one sub-pixel unit. The thin film transistor serves as a control switch in the display device and directly relates to the development direction of the high-performance flat-panel display device.

With the development of technology, there occurs the thin film transistor with metal oxide (e.g., indium gallium zinc oxide (IGZO)) as a semiconductor layer in the prior production technology of array substrate. The metal oxide thin film transistor may achieve significantly improved mobility, so that the integration of display panel is further improved. However, since the metal oxide (e.g., IGZO) is likely to be affected by ambient moisture and so on, and the metal oxide semiconductor layer may be corroded when a source and a drain on the semiconductor layer are formed by etching, an etch stop layer (referred to as ESL) is required to be fabricated on the semiconductor layer, so as to protect the metal oxide semiconductor layer during the course of forming the source and the drain by etching, so that the metal oxide semiconductor layer is not likely to be corroded by the etchant.

Generally, during the course of fabricating the array substrate including the metal oxide thin film transistor, the less the number of used mask plates is, i.e., the less the number of performed patterning processes is, the higher the productivity is, and the lower the cost is. After the etch stop layer is fabricated, however, in order to ensure electrical connection between a common electrode line provided in the same layer as a gate and a common electrode in the array substrate (ADS type) or a common electrode in a color filter substrate (TN type), a method of fabricating the array substrate including the metal oxide thin film transistor becomes relatively complicated, for example, six patterning processes are required to fabricate the typical TN type array substrate, and eight patterning processes are required to fabricate the ADS type array substrate.

As shown in FIGS. 1A through 1F (curves in vertical direction in FIGS. 1A through 1F indicate that figures at left and right sides are obtained from different cross sections, hereinafter curves in drawings of embodiments indicate the same), in the prior art, the eight patterning processes for fabricating the ADS type array substrate are as follows.

Referring to FIG. 1A, a pattern including a gate 2, a gate line (not illustrated in FIG. 1A) and a common electrode line 21 are formed on a substrate 1 by a first patterning process.

Referring to FIG. 1B, a pattern including a gate insulation layer 3 is formed by a second patterning process with SiOₓ material, wherein a contact via hole 31 is provided in the gate insulation layer 3 above the common electrode line 21.

Referring to FIG. 1C, a pattern including a semiconductor layer 4 is formed by a third patterning process with metal oxide material.

Referring to FIG. 1D, a pattern including an etch stop layer 5 is formed by a fourth patterning process with SiOₓ material, wherein a source via hole 51 and a drain via hole 52 are provided in the etch stop layer 5.

Referring to FIG. 1E, a pattern including a source 6, a drain 7, a common electrode connection line 12 and a data line (not illustrated in FIG. 1E) is formed by a fifth patterning process, wherein the source 6 is connected to the semiconductor layer 4 through the source via hole 51, and the drain 7 is connected to the semiconductor layer 4 through the drain via hole 52.

Referring to FIG. 1F, a pattern including a pixel electrode 9, a pattern including a passivation layer 8 and a pattern including a common electrode 10 are formed by three patterning processes, respectively, wherein the common electrode 10 is connected to the common electrode line 21 by the common electrode connection line 12.

As can be seen from the above, eight patterning processes are generally required in the prior method of fabricating the ADS type array substrate, and six patterning processes are generally required in the prior method of fabricating the TN type array substrate, which may result in low production efficiency and high cost, and may have a great impact on productivity.

### SUMMARY OF THE INVENTION

In order to solve the technical problem existing in the prior art in which eight patterning processes are required to fabricate the ADS type array substrate, the present invention provides a method of fabricating an array substrate, an array substrate, and a display device, which may reduce the number of patterning processes, simplify the fabricating procedure, improve the production efficiency, and reduce the cost of production.

The embodiments of the present invention provide a method of fabricating an array substrate, including steps of forming a thin film transistor, a pixel electrode and a common electrode line, wherein the step of forming the thin film transistor includes steps of forming patterns of a gate, a gate insulation layer, a semiconductor layer, an etch stop layer, a source and a drain, and the gate and the common electrode line are formed in the same layer. In the method, a gate insulation film and a semiconductor film are sequentially formed, and a pattern including the semiconductor layer is formed by one patterning process; and then an etch stop film is formed, and a pattern including the gate insulation layer and the etch stop layer is formed by one patterning process.

The step of forming the pattern including the gate insulation layer and the etch stop layer by one patterning process includes forming the pattern of the gate insulation layer and the pattern of the etch stop layer which have the same projection area by one patterning process; and the pattern including the gate insulation layer and the etch stop layer includes a contact via hole provided above the common electrode line and penetrating the gate insulation layer and the etch stop layer, a source via hole provided above the gate and corresponding to a region for forming the source, and a drain via hole provided above the gate and corresponding to a region for forming the drain; and the etch stop layer covers the gate insulation layer.

The step of forming the pattern including the gate insulation layer and the etch stop layer by one patterning process includes: removing photoresist in a region corresponding to the source via hole and provided on the etch stop film, photoresist in a region corresponding to the drain via hole and provided on the etch stop film, and photoresist in a region corresponding to the contact via hole and provided above the common electrode line, by using a dual-tone mask process; and performing a dry etching on the etch stop film and the gate insulation film to form the pattern including the etch stop layer and the gate insulation layer.

Before sequentially forming the gate insulation film and the semiconductor film, a pattern including the gate, the gate line and the common electrode line may be formed.

After forming the pattern including the gate insulation layer and the etch stop layer, a pattern including the source, the drain, a data line and a common electrode connection line may be further formed so that the source at least completely covers the source via hole and is electrically connected to the semiconductor layer, the drain at least completely covers the drain via hole and is electrically connected to the semiconductor layer, the common electrode connection line is electrically connected to the common electrode line, and the data line is electrically connected to the source.

After forming the pattern including the source, the drain and the data line, a pattern including the pixel electrode may be further formed so that the pixel electrode is electrically connected to the drain.

The embodiments of the present invention provide a method of fabricating an array substrate, including steps of forming a thin film transistor, a pixel electrode and a common electrode line, wherein the step of forming the thin film transistor including steps of forming patterns of a gate, a gate insulation layer, a semiconductor layer, an etch stop layer, a source and a drain, and the gate and the common electrode line are formed in the same layer. In the method, a semiconductor film and an etch stop film are sequentially formed, and a pattern including the semiconductor layer and the etch stop layer is formed by one patterning process.

The step of forming the pattern including the semiconductor layer and the etch stop layer by one patterning process includes forming the pattern of the semiconductor layer and the pattern of the etch stop layer which have the same projection area by one patterning process.

The step of forming the pattern including the semiconductor layer and the etch stop layer by one patterning process includes: removing photoresist in a region other than the region corresponding to the pattern of the semiconductor layer by using a dual-tone mask process; performing a dry etching on the etch stop film to remove the etch stop film in the region other than the region corresponding to the pattern of the semiconductor layer, so as to expose the semiconductor film in the region other than the region corresponding to the pattern of the semiconductor layer; performing a wet etching on the exposed semiconductor film to remove the semiconductor film in the region other than the region corresponding to the pattern of the semiconductor layer, so as to form the pattern including the semiconductor layer; removing photoresist provided above the semiconductor layer and provided in a region corresponding to a pattern including a source via hole and a drain via hole by using a dual-tone mask process, so as to expose the etch stop film in the region corresponding to the pattern including the source via hole and the drain via hole; and performing a dry etching on the exposed etch stop layer to form the pattern including the etch stop layer, wherein the pattern of the etch stop layer includes the source via hole corresponding to the region for forming the source and the drain via hole corresponding to the region for forming the drain, which are provided on the semiconductor layer.

Before sequentially forming the semiconductor film and the etch stop film, a pattern including the gate, the gate line and the common electrode line and a pattern including the gate insulation layer are formed so that the pattern including the gate insulation layer includes a pattern of a contact via hole provided on the common electrode line.

After forming the pattern including the semiconductor layer and the etch stop layer, a pattern including the source, the drain, a data line and a common electrode connection line is further formed so that the source at least completely covers the source via hole and is electrically connected to the semiconductor layer, the drain at least completely covers the drain via hole and is electrically connected to the semiconductor layer, the common electrode connection line is electrically connected to the common electrode line, and the data line is electrically connected to the source.

After forming the pattern including the source, the drain and the data line, a pattern including the pixel electrode is further formed so that the pixel electrode is electrically connected to the drain.

In the above methods, the semiconductor layer may be made of metal oxide, and the metal oxide comprises indium gallium zinc oxide (IGZO), indium zinc oxide, indium tin oxide or indium gallium tin oxide.

The above methods may further include steps of forming a passivation layer and a common electrode, wherein the passivation layer is provided between the pixel electrode and the common electrode, the passivation layer is provided with a passivation-layer via hole in a region located above the common electrode line, and the common electrode is electrically connected to the common electrode line via the common electrode connection line through the passivation-layer via hole.

The embodiments of the present invention provide an array substrate fabricated by using the above method.

The embodiments of the present invention provide a display device including the above array substrate.

According to the method of fabricating the array substrate in the embodiments of the present invention, during the course of fabricating the thin film transistor with metal oxide (e.g., IGZO), one patterning process is reduced, the fabricating procedure is simplified, the productivity of the array substrate is improved, the production efficiency is improved, and the cost of production is reduced.

### BRIEF DESCRIPTION OF THE DRAWINGS

FIGS. 1A through 1F are cross sectional views of structures formed in respective steps of a method of fabricating an array substrate in the prior art.

FIGS. 2A through 2G are cross sectional views of structures formed in respective steps of a method of fabricating an array substrate according to a first embodiment of the present invention.

FIGS. 3A through 3K are cross sectional views of structures formed in respective steps of a method of fabricating an array substrate according to a second embodiment of the present invention.

FIG. 4 is a structural schematic view of an array substrate according to a third embodiment of the present invention.

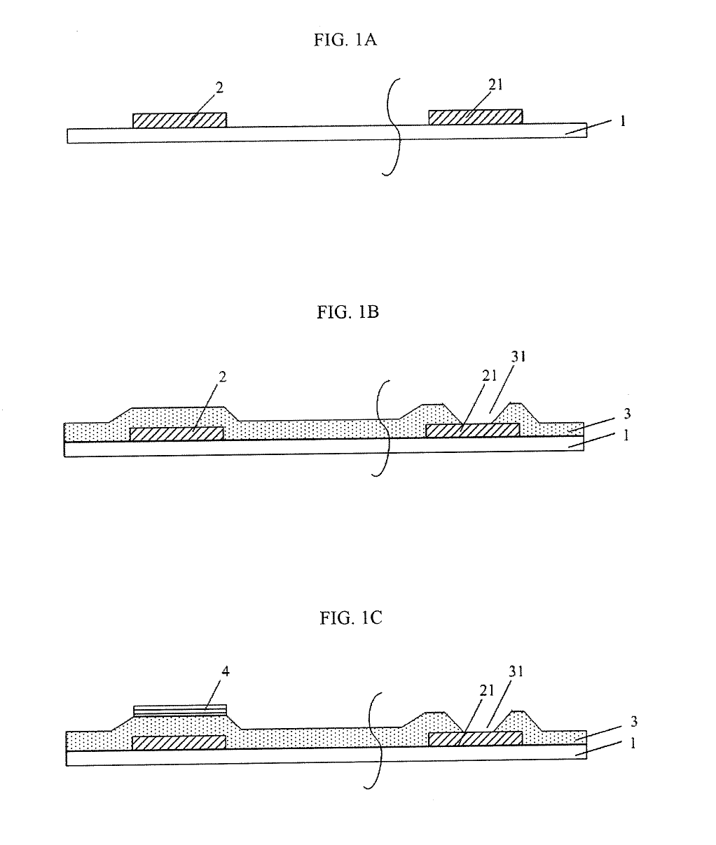

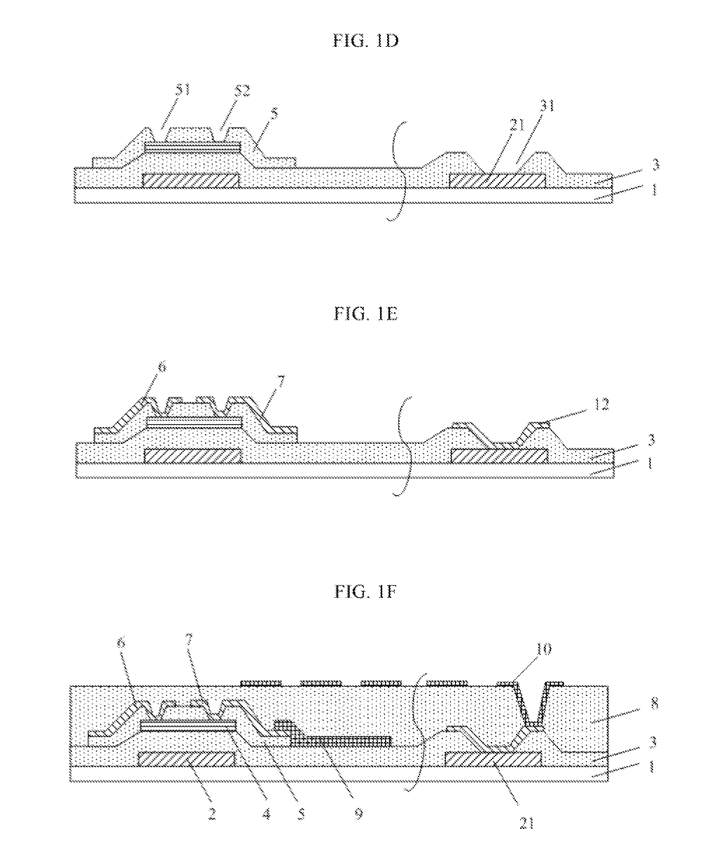

### DESCRIPTION OF THE PREFERRED EMBODIMENT

Hereinafter, for the person skilled in the art to better understand the technical solution of the present invention, a method of fabricating an array substrate, an array substrate, and a display device will be described in detail with reference to the accompanying drawings and the exemplary embodiments.

In the present invention, a photolithography process refers to a process which includes procedures of exposing, developing, etching etc., and which performs etching to form a pattern by using photoresist, a mask plate, an exposure machine etc. The patterning process includes not only the photolithography process, but also includes other process for forming a predetermined pattern, such as printing, inkjetting and so on.

### First Embodiment

This embodiment provides a method of fabricating an array substrate, including steps of forming a thin film transistor, a pixel electrode, a common electrode line, and a gate line and a data line which are electrically connected to the thin film transistor, the step of forming the thin film transistor includes steps of forming patterns of a gate, a gate insulation layer; a semiconductor layer, an etch stop layer, a source and a drain, the gate and the common electrode line are formed on the same layer. In the method of fabricating the array substrate in the embodiment, a gate insulation film and a semiconductor film are sequentially formed, and a pattern including the semiconductor layer is formed by one patterning process; and then an etch stop film is formed, and a pattern including the gate insulation layer and the etch stop layer is formed by one patterning process.

In the method, the step of forming the pattern including the gate insulation layer and the etch stop layer by one patterning process includes forming the pattern of the gate insulation layer and the pattern of the etch stop layer which have the same projection area by one patterning process, the pattern including the gate insulation layer and the etch stop layer includes a contact via hole provided on the common electrode line and penetrating the gate insulation layer and the etch stop layer, a source via hole provided above the gate to correspond to a region for forming the source, and a drain via hole provided above the gate to correspond to a region for forming the drain, and the etch stop layer covers the gate insulation layer. In a patterning process, a predetermined pattern on a mask plate is duplicated on the photoresist layer by an exposing process, and the photoresist other than that with the predetermined pattern in the photoresist layer is removed by a developing process. Since the pattern of the gate insulation layer and the pattern of the etch stop layer are simultaneously formed by a single patterning process and have the predetermined pattern on a single mask plate, ideally, the pattern of the gate insulation layer and the pattern of the etch stop layer have the same projection area (ignoring the influence of vias formed therein).

Specifically, before sequentially forming the gate insulation film and the semiconductor film, a pattern including the gate, the gate line and the common electrode line is formed.

When forming the pattern including the gate insulation layer and the etch stop layer by one patterning process, photoresist on the etch stop film corresponding to the region for forming the source via hole, photoresist on the etch stop film corresponding to the region for forming the drain via hole, and photoresist in the region corresponding to the contact via hole and provided above the common electrode line are removed by using a dual-tone mask process. The dual-tone mask process such as a half-tone mask process or a gray-tone mask process facilitates the formation of photoresist with different thicknesses, so that a layer structure having a distribution of different thicknesses can be formed by a single mask plate, and the cost of mask plate can be saved.

A dry etching is performed on the etch stop film and the gate insulation film to form the pattern including the etch stop layer and the gate insulation layer, the pattern of the gate insulation layer and the etch stop layer includes the contact via hole provided on the common electrode line and penetrating the gate insulation layer and the etch stop layer, the source via hole provided above the gate to correspond to the region for forming the source, and the drain via hole provided above the gate to correspond to the region for forming the drain, and the etch stop layer covers the gate insulation layer.

After forming the pattern including the gate insulation layer and the etch stop layer, a pattern including the source, the drain, the data line and the common electrode connection line is further formed, the source at least completely covers the source via hole, the drain at least completely covers the drain via hole, and the data line is electrically connected to the source.

After forming the pattern including the source, the drain and the data line, a pattern including the pixel electrode is further formed, and the pixel electrode is electrically connected to the drain.

For example, the semiconductor layer may be made of metal oxide, and the metal oxide comprises indium gallium zinc oxide (IGZO), indium zinc oxide, indium tin oxide or indium gallium tin oxide.

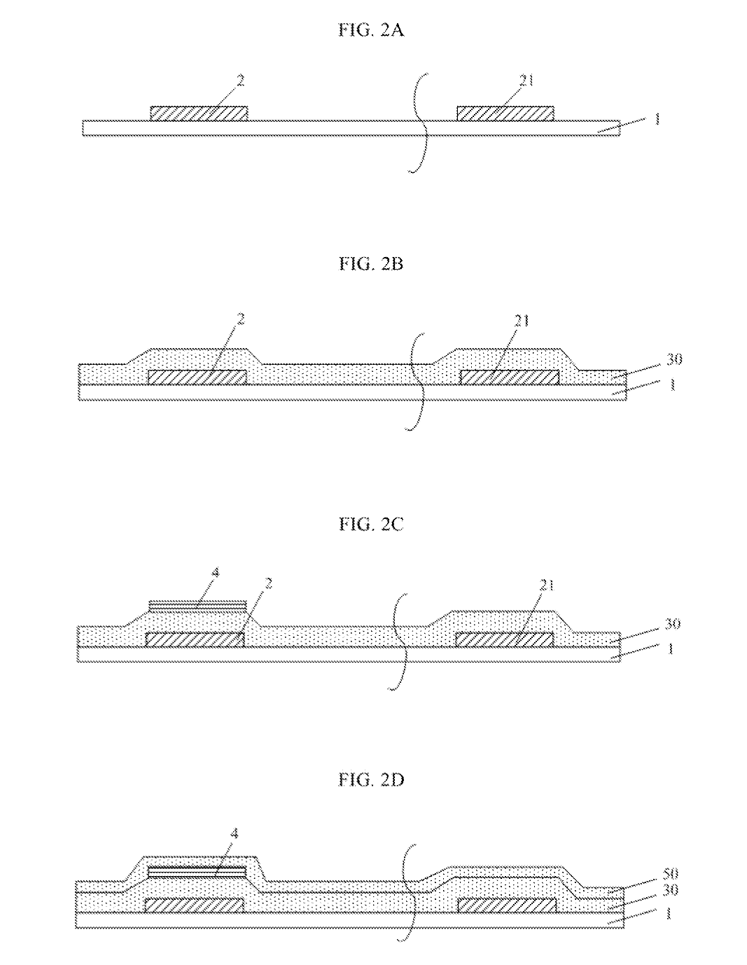

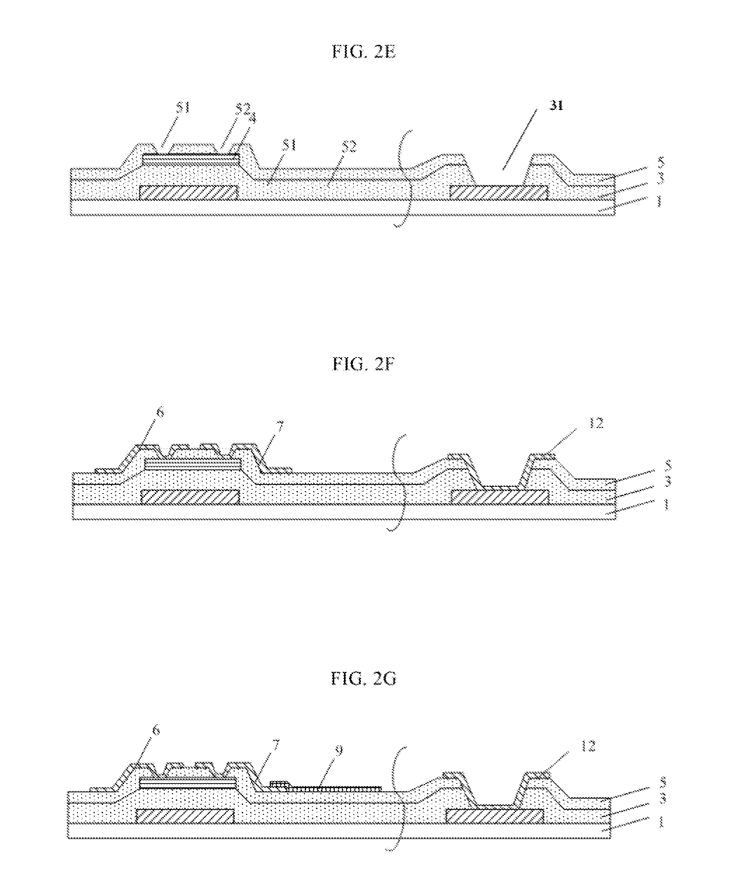

Specifically, the method of fabricating the array substrate in the embodiment may include steps as shown in FIGS. 2A through 2G.

Referring to FIG. 2A, the gate electrode film is deposited on the substrate 1 (for example, by using Mo material), and the pattern including the gate 2, the gate line (not illustrated in FIG. 2A) and the common electrode line 21 is formed by a first patterning process.

Referring to FIG. 2B, the gate insulation film 30 is deposited on the gate 2 and the common electrode line 21 (for example, by using SiOx material), but the contact hole is not formed.

Referring to FIG. 2C, the semiconductor film is deposited on the gate insulation film 30 (by using metal oxide material, for example, IGZO), and the pattern including the semiconductor layer 4 is formed by a second patterning process.

Referring to FIG. 2D, the etch stop film 50 is deposited on the semiconductor layer 4 (for example, by using SiOx material).

Referring to FIG. 2E, the pattern including the gate insulation layer 3 and the etch stop layer 5 is formed by a third patterning process.

Specifically, the photoresist is firstly coated on the etch stop film 50 to form the photoresist layer (not illustrated in FIG. 2E). Then, exposing and developing are performed on the photoresist layer by using the dual-tone mask process, so as to remove the photoresist on the etch stop film 50 corresponding to the region for forming the source via hole and the photoresist on the etch stop film 50 corresponding to the region for forming the drain via hole, and the photoresist on the etch stop film 50 corresponding to a partial region of the common electrode line 21. And then, the contact via hole 31 in the gate insulation film 30 corresponding to the location of the common electrode line 21, the source via hole 51 in the etch stop film 50 corresponding to the region for forming the source and the drain via hole 52 in the etch stop film 50 corresponding to the region for forming the drain are formed by a dry etching. During the course of performing the etching process to form the source via hole 51 and the drain via hole 52, since the semiconductor layer 4 provided below the etch stop film 50 is the metal oxide (e.g., IGZO), the dry etching condition for SiOx material of the etch stop film 50 cannot etch the metal oxide (e.g., IGZO), and thus, the contact via hole 31, the source via hole 51 and the drain via hole 52 may be formed by selecting the etching time. After the dry etching is performed, the pattern of the gate insulation layer 3 and the pattern of the etch stop layer 5 are simultaneously formed.

Referring to FIG. 2F, the source and drain electrode film is deposited on the substrate which has been subjected to the step shown in FIG. 2E (for example, by using Mo material), and the pattern including the source 6, the drain 7, data line (not illustrated in FIG. 2F) and the common electrode connection line 12 is formed by a fourth patterning process. The source 6 at least completely covers the source via hole 51 and is electrically connected to the semiconductor layer 4, the drain 7 at least completely covers the drain via hole 52 and is electrically connected to the semiconductor layer 4, the common electrode connection line 12 is electrically connected to the common electrode line 21, and the data line is electrically connected to the source 6 (not illustrated).

Referring to FIG. 2G, a transparent electrode film is formed on the source 6, the drain 7 and the data line (for example, by using ITO material), and the pattern including the pixel electrode 9 is formed by a fifth patterning process. A portion of the pixel electrode 9 is directly formed on the drain 7, and the other portion of the pixel electrode 9 is extended on the etch stop layer 5. Since the etch stop layer 5 is provided directly below the drain 7, the height difference between the pixel electrode 9 and the drain 7 at the place where the pixel electrode 9 is lapped over the drain 7 may be reduced, and thus the risk that fracture occurs in the pixel electrode 9 may be reduced.

This embodiment also provides an array substrate, which is fabricated by the above method of fabricating the array substrate.

The array substrate may be directly used for forming the TN type display panel. A color filter substrate is provided above the array substrate and is aligned with the array substrate, and the common electrode line in the array substrate is electrically connected to the common electrode in the color filter substrate. Compared with the prior art in which the TN type array substrate requires six patterning processes, this embodiment reduces one patterning process, simplifies the fabricating procedure, improves the productivity of array substrate, improves the production efficiency, and reduces the cost of production.

### Second Embodiment

This embodiment provides a method of fabricating an array substrate, including steps of forming a thin film transistor, a pixel electrode, a common electrode line, and a gate line and a data line which are electrically connected to the thin film transistor, the step of forming the thin film transistor includes steps of forming patterns of a gate, a gate insulation layer, a semiconductor layer, an etch stop layer, a source and a drain, and the gate and the common electrode line are formed in the same layer. In the method of fabricating the array substrate in the embodiment, a semiconductor film and an etch stop film are sequentially formed, and a pattern including the semiconductor layer and the etch stop layer is formed by one patterning process.

In the method, the step of forming the pattern including the semiconductor layer and the etch stop layer by one patterning process includes forming the pattern of the semiconductor layer and the pattern of the etch stop layer which have the same projection area by one patterning process.

Specifically, before sequentially forming the semiconductor film and the etch stop film, a pattern including the gate, the gate line and the common electrode line and a pattern including the gate insulation layer are formed. The pattern of the gate insulation layer includes a pattern of a contact via hole formed on the common electrode line.

When forming the pattern including the semiconductor layer and the etch stop layer by one patterning process, photoresist in a region other than the region for forming the pattern of the semiconductor layer is removed by using a dual-tone mask process: and a dry etching is performed on the etch stop film to remove the etch stop film in the region other than the region corresponding to the pattern of the semiconductor layer, so as to expose the semiconductor film in the region other than the region corresponding to the pattern of the semiconductor layer.

A wet etching is performed on the exposed semiconductor film to remove the semiconductor film in the region other than the region corresponding to the pattern of the semiconductor layer, so as to form the pattern of the semiconductor layer.

Then, photoresist above the semiconductor layer in a region for forming a pattern of a source via hole and a drain via hole is removed by using a dual-tone mask process, so as to expose the etch stop film in the region corresponding to the pattern of the source via hole and the drain via hole.

A dry etching is performed on the exposed etch stop layer to form the pattern including the etch stop layer, the pattern including the etch stop layer includes the source via hole corresponding to the region for forming the source and the drain via hole corresponding to the region for forming the drain, which are provided on the semiconductor layer.

After forming the pattern including the semiconductor layer and the etch stop layer, a pattern including the source, the drain, the data line and the common electrode connection line is further formed, wherein the source at least completely covers the source via hole, the drain at least completely covers the drain via hole, and the data line is electrically connected to the source.

After forming the pattern including the source, the drain, the data line and the common electrode connection line, a pattern including the pixel electrode is further formed, and the pixel electrode is electrically connected to the drain.

For example, the semiconductor layer may be made of metal oxide, and the metal oxide comprises indium gallium zinc oxide (IGZO), indium zinc oxide, indium tin oxide or indium gallium tin oxide.

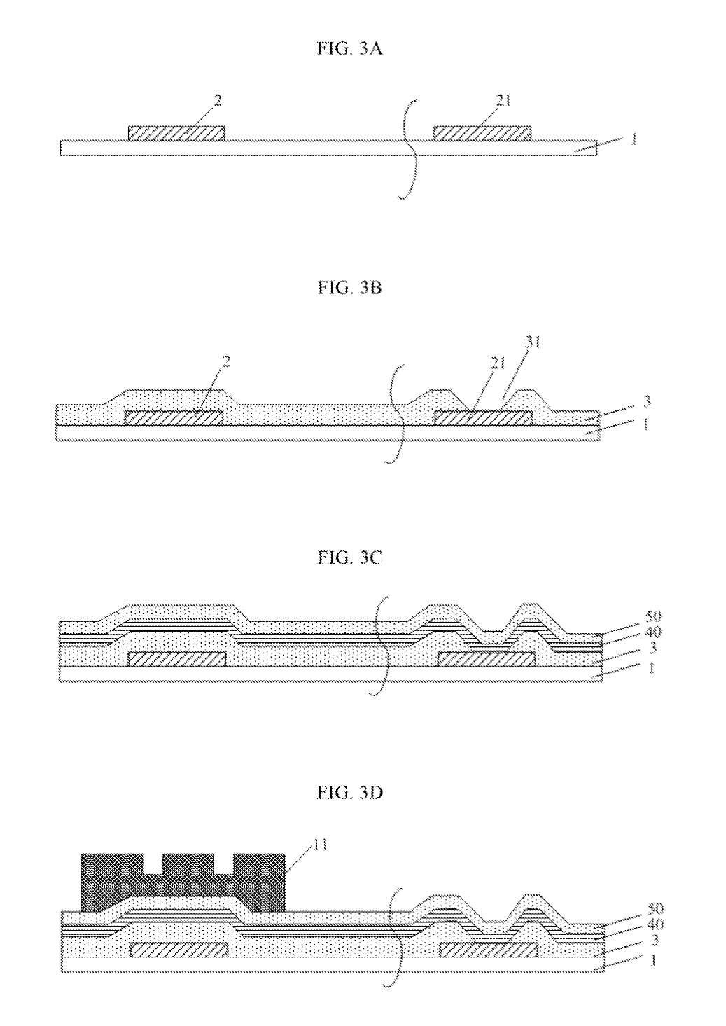

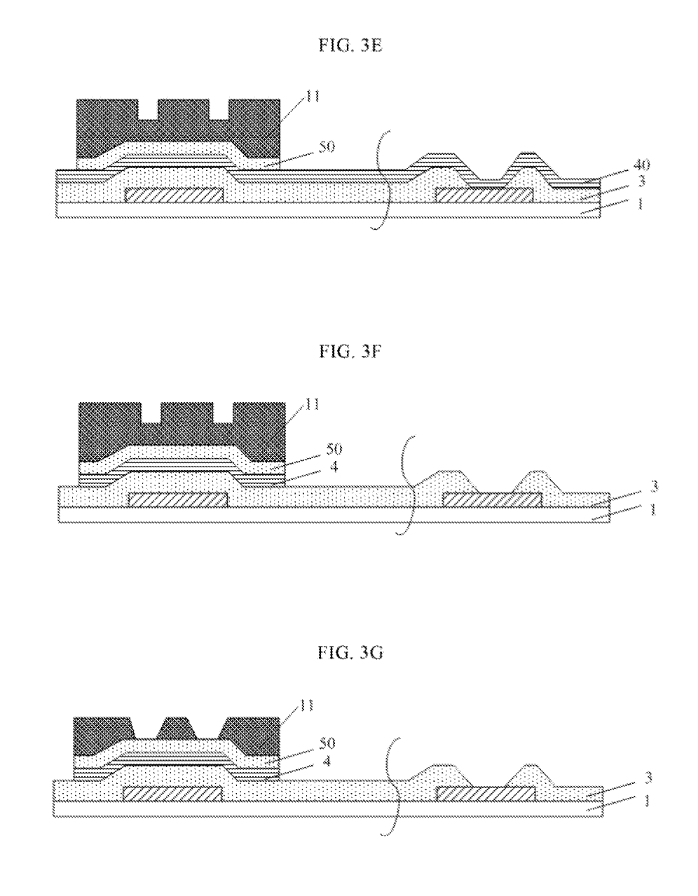

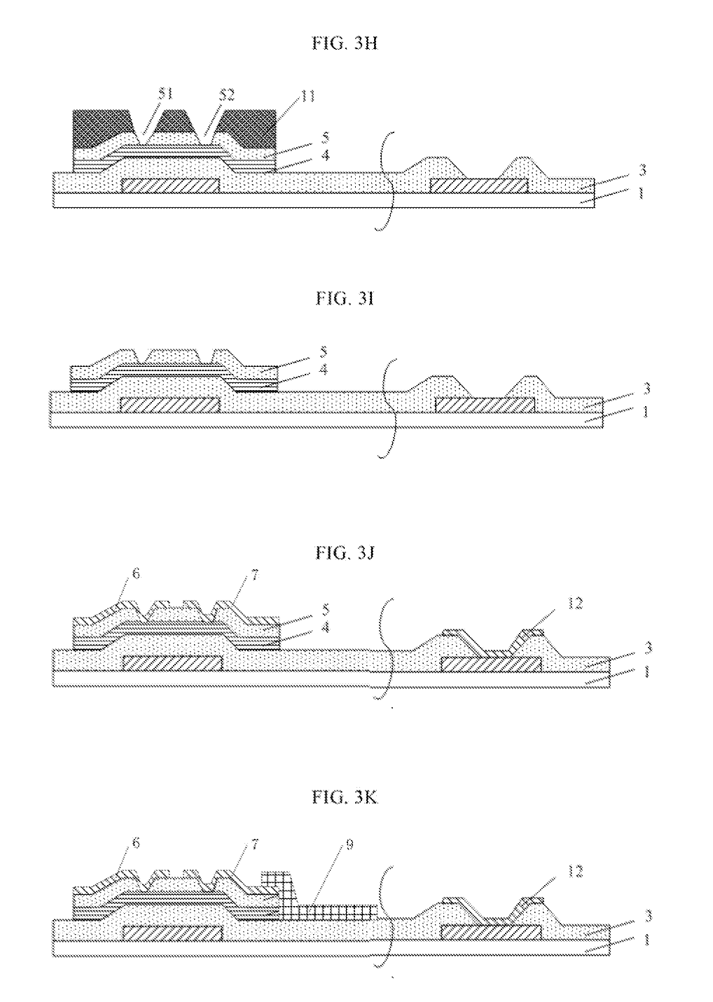

Specifically, the method of fabricating the array substrate in the embodiment may include steps as shown in FIGS. 3A through 3K.

Referring to FIG. 3A, the gate electrode film is deposited on the substrate 1 (for example, by using Mo material), and the pattern including the gate 2, the gate line (not illustrated in FIG. 3A) and the common electrode line 21 is formed by a first patterning process.

Referring to FIG. 3B, the gate insulation film is deposited on the gate 2 and the common electrode line 21 (for example, by using SiOx material), and the pattern including the gate insulation layer 3 is formed by a second patterning process, wherein the pattern of the gate insulation layer 3 includes the contact via hole 31.

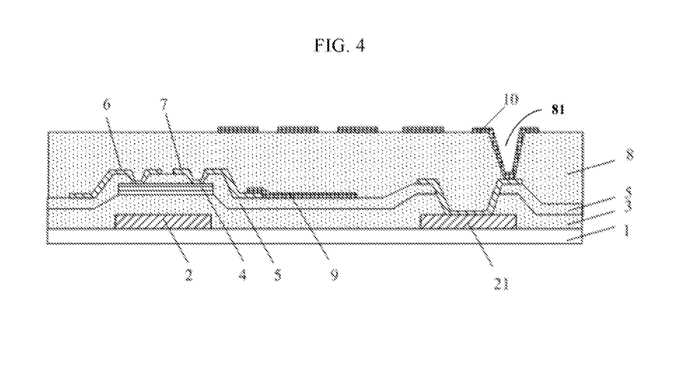

Referring to FIGS. 3C through 31, the semiconductor film 40 (of metal oxide material, for example, IGZO) and the etch stop film 50 (for example, of SiOx material) are sequentially deposited on the gate insulation layer 3, and the pattern including the semiconductor layer 4 and the etch stop layer 5 is formed by a third patterning process.

Specifically, referring to FIG. 3D, the photoresist layer 11 is firstly applied on the etch stop film 50, and the photoresist in the region other than the region for forming the pattern of the semiconductor layer is removed by a dual-tone mask process.

Referring to FIG. 3E, a dry etching is performed on the etch stop film 50 to remove the etch stop film 50 in the region other than the region corresponding to the pattern of the semiconductor layer, so as to expose the semiconductor film 40 in the region other than the region corresponding to the pattern of the semiconductor layer.

Referring to FIG. 3F, a wet etching is performed on the exposed semiconductor film 40 to remove the semiconductor film 40 in the region other than the region corresponding to the pattern of the semiconductor layer, so as to form the pattern including the semiconductor layer 4.

Referring to FIG. 3G, the photoresist which is provided above the semiconductor layer 4 and which is provided in the region for forming the pattern of the source via hole and the drain via hole is removed by a dual-tone mask process, so as to expose the etch stop film 50 in the region corresponding to the pattern of the source via hole and the drain via hole.

Referring to FIG. 3H, a dry etching is performed on the exposed etch stop film 50 to form the pattern including the etch stop layer 5, the etch stop layer 5 includes the source via hole 51 corresponding to the region for forming the source and the drain via hole 52 corresponding to the region for forming the drain which are provided on the semiconductor layer 4.

Referring to FIG. 3I, the photoresist layer 11 is peeled off. Referring to FIG. 3J, the source and drain electrode film is deposited on the substrate which has been subjected to the step shown in FIG. 3I (for example, by using Mo material), and the pattern including the source 6, the drain 7, the common electrode connection line 12 and the data line (not illustrated in FIG. 3J) is formed by a fourth patterning process. The source 6 at least completely covers the source via hole 51 and is electrically connected to the semiconductor layer 4, the drain 7 at least completely covers the drain via hole 52 and is electrically connected to the semiconductor layer 4, the common electrode connection line 12 is electrically connected to the common electrode line 21, and the data line is electrically connected to the source 6 (not illustrated).

Referring to FIG. 3K, a transparent electrode film is formed on the source 6, the drain 7 and the data line (for example, by using ITO material), and the pattern including the pixel electrode 9 is formed by a fifth patterning process, wherein the pixel electrode 9 is electrically connected to the drain 7.

This embodiment also provides an array substrate, which is fabricated by the above method of fabricating the array substrate.

The array substrate may be directly used for forming the TN type display panel. A color filter substrate is provided above the array substrate and is aligned with the array substrate, and the common electrode line in the array substrate is electrically connected to the common electrode in the color filter substrate. Compared with the prior art in which the TN type array substrate requires six patterning processes, this embodiment reduces one patterning process, simplifies the fabricating procedure, improves the productivity of array substrate, improves the production efficiency, and reduces the cost of production.

In the first and second embodiments, with the improvements on the method of fabricating the array substrate, the number of patterning processes required to fabricate the array substrate using the metal oxide (for example, IGZO) is reduced, and compared with the prior art in which the array substrate requires six patterning processes, one patterning process is saved, the fabricating procedure is simplified, the productivity of array substrate is improved, the production efficiency is increased, and the cost of production is reduced.

### Third Embodiment

This embodiment provides an array substrate including the construction of the array substrate in the first or second embodiment. In addition, the array substrate further includes a passivation layer 8 and a common electrode 10 formed above the source, the drain, the pixel electrode and the common electrode connection line.

Specifically, the passivation layer 8 is provided between the pixel electrode 9 and the common electrode 10, and the passivation layer 8 is provided with a passivation-layer via hole 81 in a region located above the common electrode line 21. The common electrode line 21 is electrically connected to the common electrode 10 via the common electrode connection line 12 through the passivation-layer via hole 81.

By additionally providing the passivation layer 8 and the common electrode 10, an ADSDS (advanced super dimension switch, simply referred to as ADS) type liquid display panel may be formed. That is, a multi-dimensional electric field may be formed by an electric field formed at edges of slit electrodes in the same plane and an electric field formed between slit electrodes and plate electrode, so that liquid crystal molecules of all orientations provided between the slit electrodes and provided directly above the electrodes in the liquid crystal cell are rotated, thereby improving the work efficiency of liquid crystal and increasing the light transmission efficiency. The advanced super dimension switch technology may improve the picture quality of TFT-LCD products and has advantages such as high resolution, high transmittance, low power consumption, wide viewing angle, high opening ratio, low color difference, no push Mura. For different applications, the improved technology for the ADS technology includes high-transmittance I-ADS technology, high-opening-ratio H-ADS technology and high-resolution S-ADS technology.

Taking the array substrate in the first embodiment as an example, referring to FIG. 5, the passivation layer 8 and the common electrode 10 are formed on the array substrate by two patterning processes. The common electrode 10 is electrically connected to the common electrode line 21 via the common electrode connection line 12 through the passivation-layer via hole 81.

In the third embodiment, the number of patterning processes required to fabricate the array substrate with the metal oxide (e.g., IGZO) is reduced by improving the method of fabricating the array substrate. Compared with the prior art in which the ADS type array substrate requires eight patterning processes, this embodiment reduces one patterning process, simplifies the fabricating procedure, improves the productivity of array substrate, improves the production efficiency, and reduces the cost of production.

### Fourth Embodiment

This embodiment provides a display device including the array substrate in any one of the first through third embodiments.

The display device may be applicable to desktop computers, tablet computers, laptops, cell phones, PDA, GPS, automotive displays, projection displays, camcorders, digital cameras, electronic watches, calculators, electronic equipments, instruments, LCD panels, electronic paper, TV, monitors, digital photo frames, navigation systems and any other product or component that has a display function, and can be used in fields of public display and unreal display.

It should be appreciated that the above embodiments are only the exemplary embodiments employed for illustrating the principle of the present invention, but the present invention is not limited thereto. It will be apparent to those skilled in the art that modifications and variations can be made without departing from the spirit and scope of the present invention, and these modifications and variations are also considered to fall within the scope of protection of the present invention.

1. A method of fabricating an array substrate, including steps of forming a thin film transistor, a pixel electrode and a common electrode line, wherein the step of forming the thin film transistor includes steps of forming patterns of a gate, a gate insulation layer, a semiconductor layer, an etch stop layer, a source and a drain, and the gate and the common electrode line are formed in the same layer, and
wherein the steps of forming patterns of a gate, a gate insulation layer, a semiconductor layer, an etch stop layer, a source and a drain include: sequentially forming a gate insulation film and a semiconductor film, and forming a pattern including the semiconductor layer by one patterning process; and then forming an etch stop film, and forming a pattern including the gate insulation layer and the etch stop layer by one patterning process.

2. The method of claim 1, wherein the step of forming the pattern including the gate insulation layer and the etch stop layer by one patterning process includes forming the pattern of the gate insulation layer and the pattern of the etch stop layer which have the same projection area by one patterning process, and
the pattern including the gate insulation layer and the etch stop layer includes a contact via hole provided above the common electrode line and penetrating, the gate insulation layer and the etch stop layer, a source via hole provided above the gate and corresponding to a region for forming the source, and a drain via hole provided above the gate and corresponding to a region for forming the drain, and
the etch stop layer covers the gate insulation layer.

3. The method of claim 2, wherein the step of forming the pattern including the gate insulation layer and the etch stop layer by one patterning process includes:
removing photoresist in a region corresponding to the source via hole and provided, on the etch stop film, photoresist in a region corresponding to the drain via hole and provided on the etch stop film, and photoresist in a region corresponding to the contact via hole and provided above the common electrode line, by using a dual-tone mask process; and
performing a dry etching on the etch stop film and the gate insulation film to form the pattern including the etch stop layer and the gate insulation layer.

4. The method of claim 3, further including steps of:
forming a pattern including the gate, the gate line and the common electrode line before sequentially forming the gate insulation film and the semiconductor film;
forming a pattern including the source, the drain, a data line and a common electrode connection line after forming the pattern including the gate insulation layer and the etch stop layer, so that the source at least completely covers the source via hole and is electrically connected to the semiconductor layer, the drain at least completely covers the drain via hole and is electrically connected to the semiconductor layer, the common electrode connection line is electrically connected to the common electrode line, and the data line is electrically connected to the source; and
forming a pattern including the pixel electrode after forming the pattern including the source, the drain and the data line, so that the pixel electrode is electrically connected to the drain.

5. The method of claim 1, wherein the semiconductor layer is made of metal oxide, and the metal oxide comprises indium gallium zinc oxide, indium zinc oxide, indium tin oxide or indium gallium tin oxide.

6. The method of claim 4, further including steps of forming a passivation layer and a common electrode, wherein the passivation layer is provided between the pixel electrode and the common electrode, the passivation layer is provided with a passivation-layer via hole in a region located above the common electrode line, and the common electrode is electrically connected to the common electrode line via the common electrode connection line through the passivation-layer via hole.

7. A method of fabricating an array substrate, including steps of forming a thin film transistor, a pixel electrode and a common electrode wherein the step of forming the thin film transistor includes steps of forming patterns of a gate, a gate insulation layer, a semiconductor layer, an etch stop layer, a source and a drain, and the gate and the common electrode line are formed in the same layer, and
wherein the steps of forming patterns of a gate, a gate insulation layer, a semiconductor layer, an etch stop layer, a source and a drain include: sequentially forming a semiconductor film and an etch stop film, and forming a pattern including the semiconductor layer and the etch stop layer by one patterning process.

8. The method of claim 7, wherein the step of forming the pattern including the semiconductor layer and the etch stop layer by one patterning process includes forming the pattern of the semiconductor layer and the pattern of the etch stop layer which have the same projection area by one patterning process.

9. The method of claim 8, wherein the step of forming the pattern including the semiconductor layer and the etch stop layer by one patterning process includes:
removing photoresist in a region other than the region corresponding to the pattern of the semiconductor layer by using a dual-tone mask process;
performing a dry etching on the etch stop film to remove the etch stop film in the region other than the region corresponding to the pattern of the semiconductor layer, so as to expose the semiconductor film in the region other than the region corresponding to the pattern of the semiconductor layer;
performing a wet etching on the exposed semiconductor film to remove the semiconductor film in the region other than the region corresponding to the pattern of the semiconductor layer, so as to form the pattern including the semiconductor layer;
removing photoresist provided above the semiconductor layer and provided in a region corresponding to a pattern including a source via hole and a drain via hole by using a dual-tone mask process, so as to expose the etch stop film in the region corresponding to the pattern including the source via hole and the drain via hole; and
performing a dry etching on the exposed etch stop layer to form the pattern including the etch stop layer, wherein the pattern of the etch stop layer includes the source via hole corresponding to the region for forming the source and the drain via hole corresponding to the region for forming the drain, which are provided on the semiconductor layer.

10. The method of claim 9, further including steps of:
forming a pattern including the gate, the gate line and the common electrode line and a pattern including the gate insulation layer before sequentially forming the semiconductor film and the etch stop film, so that the pattern including the gate insulation layer includes a pattern of a contact via hole provided on the common electrode line;
forming a pattern including the source, the drain, a data line and a common electrode connection line after forming the pattern including the semiconductor layer and the etch stop layer, so that the source at least completely covers the source via hole and is electrically connected to the semiconductor layer, the dram at least completely covers the drain via hole and is electrically connected to the semiconductor layer, the common electrode connection line is electrically connected to the common electrode line, and the data line is electrically connected to the source; and
forming a pattern including the pixel electrode after forming the pattern including the source, the drain and the data line, so that the pixel electrode is electrically connected to the drain.

11. The method of claim 7, wherein the semiconductor layer is made of metal oxide, and the metal oxide comprises indium gallium zinc oxide, indium zinc oxide, indium tin oxide or indium gallium tin oxide.

12. The method of claim 10, further including steps of forming a passivation layer and a common electrode, wherein the passivation layer is provided between the pixel electrode and the common electrode, the passivation layer is provided with a passivation-layer via hole in a region located above the common electrode line, and the common electrode is electrically connected to the common electrode line via the common electrode connection line through the passivation-layer via hole.

13. An array substrate, fabricated by using the method of claim 1.
